(19) United States
(12) Patent Application Publication
(10) Pub. No.: US 2026/0031169 A1
(43) Pub. Date: Jan. 29, 2026

(54) SCAN TIMING MANAGEMENT FOR A MEMORY SYSTEM

(71) Applicant: Micron Technology, Inc., Boise, ID (US)

(72) Inventors: Alessandro Magnavacca, Sesto San Giovanni (Milano) (IT); Ciro Feliciano, Casandrino (NA) (IT); Michela Spagnolo, Sesto San Giovanni (IT); Pierluigi Manzo, Napoli (IT)

(21) Appl. No.: 19/274,308

(22) Filed: Jul. 18, 2025

Related U.S. Application Data
(60) Provisional application No. 63/675,044, filed on Jul. 24, 2024.

(51) Int. Cl. G11C 29/12

(52) U.S. Cl. CPC G11C 29/12005

(57) ABSTRACT

Methods, systems, and devices for scan timing management for a memory system are described. A timing for performing a media scan may be dynamically adjusted based on results of a block family scan. After a memory system is powered on, the block family scan may be triggered and the memory system may use the results of the block family scan to determine whether to immediately perform the media scan. Performing the block family scan may identify read voltages, and a change in the read voltages since before the memory system was powered on. The memory system may trigger to immediately perform the media scan if the read voltages or the change in the read voltages satisfy thresholds. However, the memory system may not perform the media scan until a media scan timer is satisfied, if the read voltages and the change in the read voltages do not satisfy the thresholds.

### CROSS REFERENCE

The present Application for Patent claims priority to U.S. Patent Application No. 63/675,044 by Magnavacca et al., entitled “SCAN TIMING MANAGEMENT FOR A MEMORY SYSTEM,” filed Jul. 24, 2024, which is assigned to the assignee hereof, and which is expressly incorporated by reference in its entirety herein.

### TECHNICAL FIELD

The following relates to one or more systems for memory, including scan timing management for a memory system.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports scan timing management for a memory system in accordance with examples as disclosed herein.

FIG. 2 shows an example of a process flow that supports scan timing management for a memory system in accordance with examples as disclosed herein.

FIG. 3 shows a block diagram of a memory system that supports scan timing management for a memory system in accordance with examples as disclosed herein.

FIG. 4 shows a flowchart illustrating a method or methods that support scan timing management for a memory system in accordance with examples as disclosed herein.

### DETAILED DESCRIPTION

Some memory systems may be configured to perform various scan operations to detect operating parameters and retention information of the memory systems. For example, a memory system may be configured to perform a block family scan, in which the memory system may determine and improve read voltages associated with reading (e.g., magnitudes of voltages applied to memory cells as part of a read operation) memory cells of the memory system. Additionally, or alternatively, the memory system may be configured to perform a media scan, in which the memory system may determine a health of the memory system by measuring retention and/or degradation parameters (e.g., of data, of blocks) of the memory system, such that a refresh operation may be triggered to improve the retention and/or degradation (e.g., of data, of blocks) of the memory system. In some cases, the block family scan may be triggered based on a block family scan timer being satisfied, and the media scan may be triggered based on a media scan timer being satisfied. In some such cases, the block family scan timer may be associated with a relatively smaller duration than an average duration in which the memory system is powered down (e.g., before being powered on again). Conversely, the media scan timer may be associated with a relatively longer duration than the average duration in which the memory system is powered down. That is, the block family scan timer and the media scan timer may not continue running when the memory system is powered down.

In some examples, after the memory system is powered down, the block family scan may be triggered once the memory system is powered on again regardless of a value (e.g., a pre-power down value) of the block family scan timer, due to the block family scan timer being associated with a relatively smaller duration than the average duration of the power down. In some such examples, after the memory system is powered down, the media scan may not be triggered once the memory system is powered on again, due to the media scan timer being associated with a relatively longer duration than the average duration of the power down. However, in some examples, the duration in which the memory system is powered down may be greater than the duration of the media scan timer, yet the media scan may not be triggered because the media scan timer may continue from a pre-power down value. In some such examples, refraining from performing the media scan may result in retention or degradation due to the media scan not being performed after the memory system is powered on. In some cases, the media scan may be automatically initiated after the memory system is powered on (e.g., after a power down), regardless of a value (e.g., a pre-power down value of the media scan timer. However, in some examples, the duration in which the memory system is powered down may be less than the duration of the media scan timer, yet because the media scan is automatically initiated regardless, the memory system may experience latency and bandwidth consumption due to the unnecessary media scan.

In accordance with examples as described herein, a timing for performing the media scan may be dynamically adjusted based on results of a block family scan following a power on of the memory system. That is, after the memory system is powered down, the block family scan may be automatically triggered once the memory system is power on again, and the memory system may use the results of the block family scan to determine whether to immediately perform the media scan or refrain from performing the media scan until the media scan timer is satisfied. For example, performing the block family scan may include identifying a magnitude of the read voltage used for a subset of blocks (e.g., blocks with a lowest bin value, blocks with a highest read voltage) of the memory system, and determining whether there has been a change in magnitude of the read voltage used for the subset of blocks since before the memory system was powered down. A bin value for a block may correspond to a range of voltages that includes a voltage associated with reading memory cells within the block. The memory system may trigger to immediately perform the media scan if the magnitude of the read voltage satisfies a threshold (e.g., bin value satisfies a threshold), or if the change in magnitude of the read voltage satisfies a threshold (e.g., change in bin value satisfies a threshold). However, the memory system may refrain from performing the media scan until the media scan timer is satisfied if the change in magnitude of the read voltage does not satisfy the threshold, and if the magnitude of the read voltage does not satisfy the threshold.

Dynamically adjusting the timing for performing the media scan may prevent retention and/or degradation of the memory system otherwise associated with not performing the media scan after the memory system is powered down (e.g., and powered on again), among other potential benefits. Likewise, dynamically adjusting the timing for performing the media scan may prevent latency and bandwidth consumption otherwise associated with performing an unnecessary media scan after the memory system is powered down (e.g., and powered on again).

In addition to applicability in memory systems as described herein, techniques for scan timing management for a memory system may be generally implemented to improve the performance of various electronic devices and systems (including artificial intelligence (AI) applications, augmented reality (AR) applications, virtual reality (VR) applications, automotive applications, and gaming). Some electronic device applications, including high-performance applications such as AI, AR, VR, automotive, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of automotive or electronic devices by dynamically adjusting the timing for performing a media scan, which may decrease processing or latency times, improve response times, or otherwise improve user experience, among other benefits.

Features of the disclosure are illustrated and described in the context of systems, devices, and circuits. Features of the disclosure are further illustrated and described in the context of a process flow and a flowchart.

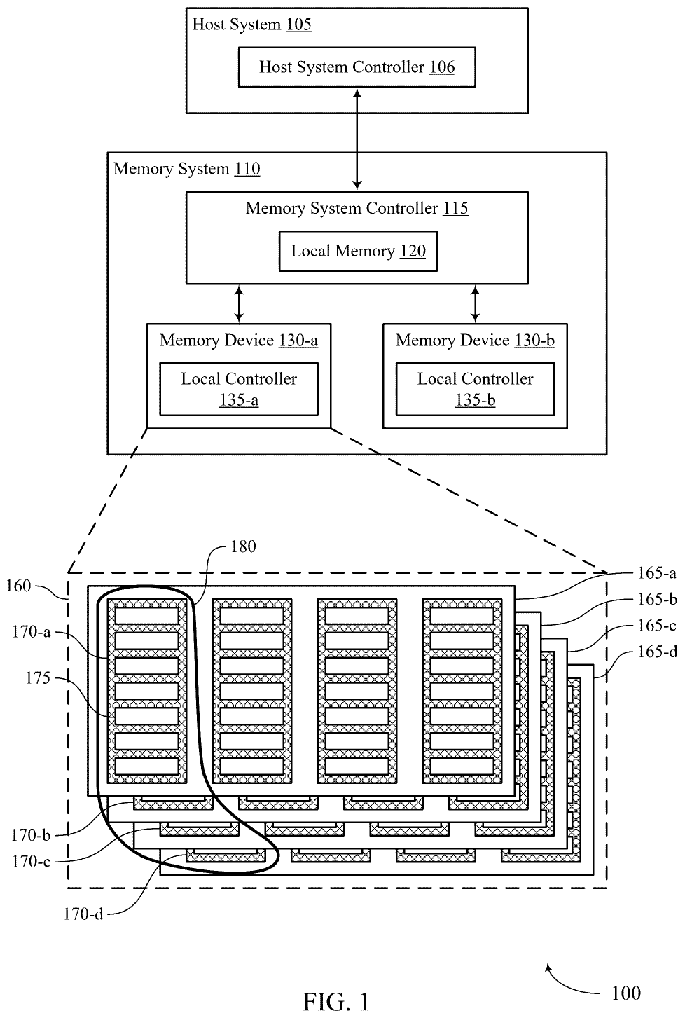

FIG. 1 shows an example of a system 100 that supports scan timing management for a memory system in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IOT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof.

Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, L2P mapping tables may be maintained and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has not been written to or that has been erased.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

The memory system 110 may be configured to perform various scan operations to detect operating parameters and retention information of the memory system 110. For example, the memory system 110 may be configured to perform a block family scan, in which the memory system 110 may determine and improve read voltages associated with reading (e.g., magnitudes of voltages applied to memory cells as part of a read operation) memory cells of the memory system 110. Additionally, or alternatively, the memory system 110 may be configured to perform a media scan, in which the memory system 110 may determine a health of the memory system 110 by measuring retention and/or degradation parameters (e.g., of data, of blocks) of the memory system 110, such that a refresh operation may be triggered to improve the retention and/or degradation (e.g., of data, of blocks) of the memory system 110. In some cases, the block family scan may be triggered based on a block family scan timer being satisfied, and the media scan may be triggered based on a media scan timer being satisfied. In some such cases, the block family scan timer may be associated with a relatively smaller duration than an average duration in which the memory system is powered down (e.g., before being powered on again). Conversely, the media scan timer may be associated with a relatively longer duration than the average duration in which the memory system is powered down. That is, the block family scan timer and the media scan timer may not continue running when the memory system is powered down.

In accordance with examples as described herein, a timing for performing the media scan may be dynamically adjusted based on results of a block family scan following a power on of the memory system 110. That is, after the memory system 110 is powered down, the block family scan may be automatically triggered once the memory system 110 is power on again (e.g., regardless of a pre-power down value of the block family scan timer), and the memory system 110 may use the results of the block family scan to determine whether to immediately perform the media scan or refrain from performing the media scan until the media scan timer is satisfied. For example, performing the block family scan may identify a magnitude of the read voltage used for a subset of blocks 170 (e.g., blocks 170 with a lowest bin value, blocks 170 with a highest read voltage), and determine if there has been a change in magnitude of the read voltage used for the subset of blocks 170 since before the memory system 110 was powered down. The memory system 110 may trigger to immediately perform the media scan if the magnitude of the read voltage satisfies a threshold, or if the change in magnitude of the read voltage satisfies a threshold. However, the memory system 110 may refrain from performing the media scan until the media scan timer is satisfied if the change in magnitude of the read voltage does not satisfy the threshold, and if the magnitude of the read voltage does not satisfy the threshold. Dynamically adjusting the timing for performing the media scan may prevent retention and/or degradation of the memory system 110 otherwise associated with not performing the media scan after the memory system 110 is powered down (e.g., and powered on again). Likewise, dynamically adjusting the timing for performing the media scan may prevent latency and bandwidth consumption otherwise associated with performing an unnecessary media scan after the memory system 110 is powered down (e.g., and powered on again).

The system 100 may include any quantity of non-transitory computer readable media that support scan timing management for a memory system. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

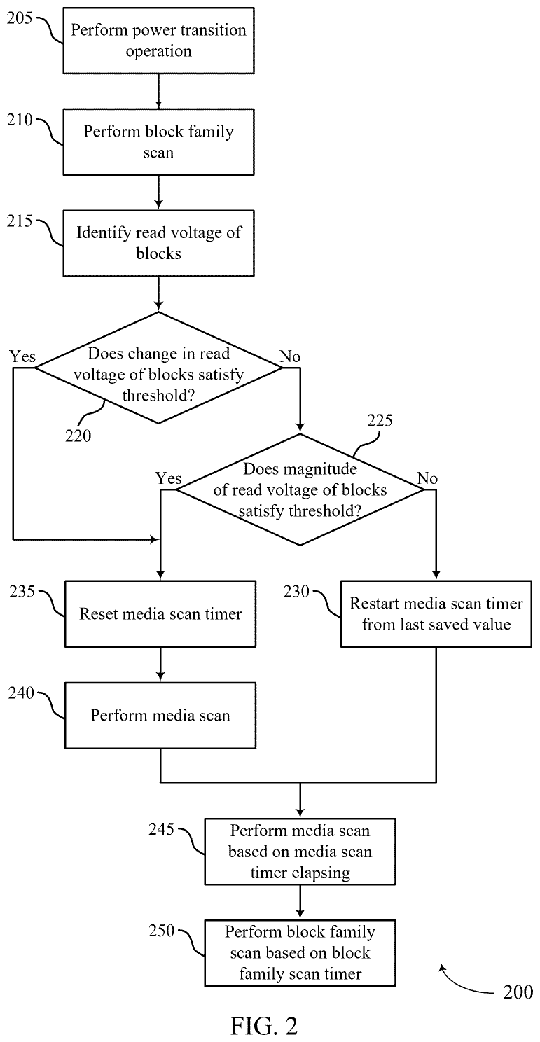

FIG. 2 shows an example of a process flow 200 that supports scan timing management for a memory system in accordance with examples as disclosed herein. The process flow 200 may implement aspects of or be implemented by a system, which may be an example of a system 100, as described with reference to FIG. 1. For example, the process flow 200 may illustrate operations of a memory system, which may be an example of a memory system 110, as described with reference to FIG. 1. The process flow 200 illustrates operations associated with dynamically adjusting a timing for performing a media scan based on results of a block family scan following a power on of the memory system.

In the following description of the process flow 200, the methods, techniques, processes, and operations may be performed in different orders or at different times. Further, some operations may be left out of the process flow 200, or other operations may be added to the process flow 200. Aspects of the process flow 200 may be implemented by one or more controllers, among other components. Additionally, or alternatively, aspects of the process flow 200 may be implemented as instructions stored in one or more memories (e.g., firmware stored in one or more memories coupled with a memory system controller 115, as described with reference to FIG. 1). For example, the instructions, when executed by one or more controllers (e.g., the memory system controller 115), may cause the one or more controllers (or a device or a system) to perform the operations of the process flow 200.

The memory system may include one or more memory system controllers (e.g., NAND controllers) configured to facilitate operations of the memory system. The memory system may also include one or more memory devices (e.g., NAND devices), which may each include one or more memory arrays (e.g., NAND arrays) and one or more local controllers. The one or more memory arrays may each include a quantity of blocks, where each block may include a quantity of memory cells (e.g., NAND cells) each configured to store one or more bits of information for the memory system. In some examples, the memory cells may be accessed based on applying a voltage to the memory cells. For example, a memory cell may be read based on applying a read voltage to the memory cell and comparing the read voltage to the cell threshold to determine its logic state.

In some cases, the memory system may be configured to perform various power transition operations to transition between various power modes. For example, the memory system may be configured to perform a power down operation (e.g., a hibernation operation, a power-off operation), in which the memory system transitions from a relatively high power mode (e.g., an active mode, an ON mode) to a relatively low power mode (e.g., a hibernation mode, a sleep mode, a deep sleep mode, an OFF mode). Likewise, the memory system may be configured to perform a power up operation (e.g., a hibernation exit operation, a power-on operation), in which the memory system transitions from the relatively low power mode to the relatively high power mode.

The memory system may be configured to perform a block family scan, in which the memory system may determine read voltages for the blocks of the memory system. The block family scan may be performed for each virtual block of the memory system, which may each include a subset of blocks (e.g., one block from each plane of the memory system). That is, the block family scan may identify read voltages which may be applied to the memory cells to read the data from the memory cells of the virtual blocks (e.g., with a quantity of errors within a threshold). In some cases, the block family scan may be used to identify magnitudes of the read voltages associated with reading data from the memory cells of the virtual blocks. In some cases, the block family scan may be used to identify a change in the magnitude of the read voltages since performing a previous block family scan or since powering down and powering on the memory system. In some cases, each read voltage may be associated with a base read voltage level (e.g., a standard read voltage) and an offset from the base read voltage level. For example, performing the block family scan may include reading data from a memory cell using the base read voltage level and determining whether the quantity of errors identified during the reading satisfies a threshold. If the quantity of errors does not satisfy the threshold, the base read voltage level may be offset and the data may be reread until the quantity of errors satisfies the threshold, at which time the read voltage may be identified. That is, some read voltages identified by the block family scan may correspond to the base read voltage level, and other read voltages may correspond to the base read voltage level and varying offsets from the base read voltage level. In some examples, the offsets may be negative magnitudes, such that a highest read voltage may correspond to the base read voltage level, and a lowest read voltage may correspond to the base read voltage level with the greatest magnitude offset applied (e.g., to the base read voltage level).

The memory system may be configured to determine bin levels associated with the read voltages based on performing the block family scan. For example, the block family scan may be used to determine a bin level for each read voltage identified during reading the memory cells. In some examples, each bin level may be associated with a read voltage or a range of read voltages. For example, a Bin 0 may be associated with a read voltage corresponding to the base read voltage level (e.g., without an offset). Likewise, a Bin 1 may be associated with a read voltage corresponding to the base read voltage level with a lowest magnitude offset (e.g., −10 mv). Further, a Bin 2 may be associated with a read voltage corresponding to the base read voltage level with an offset (e.g., −20 mv) greater in magnitude than the offset of Bin 1. In some such examples, the bin value may have an inverse relationship to read voltage value, such that the bin value may increase as read voltage value decreases, or as the magnitude of the negative offset increases. In some implementations, Bin 0 may be associated with a first read voltage range (e.g., base read voltage >−10 mv), Bin 1 may be associated with a second read voltage range (e.g., base read voltage of −10 mv to base read voltage of −20 mv), and Bin 2 may be associated with a third read voltage range (e.g., base read voltage of −20 mv to base read voltage −30 mv). Although this description includes three example bins, it should be understood that the block family scan may support more than three bins, and the voltage ranges may vary or be positive.

The memory system may be configured to perform a media scan, in which the memory system may determine health information for the blocks of the memory system. That is, the media scan may identify retention and/or degradation parameters of the blocks (e.g., virtual blocks) of the memory system. In some cases, the media scan may be used to identify read value margins of the blocks or changes in the read value margins. In some cases, the media scan may be used to identify a level of degradation of the blocks or a retention capability of the blocks. For example, the media scan may identify a level of degradation of data (e.g., error percentages of data) stored in the blocks, to determine whether the level of degradation satisfies a threshold level of degradation. The media scan may be used to determine whether to perform a refresh operation on the blocks. For example, if the level of degradation satisfies the threshold level of degradation, the memory system may perform a refresh operation on the blocks. In some implementations, performing the refresh operation may include refreshing the data stored in the blocks by copying the data from one or more blocks to one or more other blocks, or rewriting the data to the same blocks (e.g., reapplying the same voltages to the same blocks), or any combination thereof.

In some cases, the memory system may implement timers for performing the block family scan and the media scan. For example, the memory system may implement a block family scan timer, such that when the block family scan timer is satisfied, the memory system may be triggered to perform the block family scan. Likewise, the memory system may implement a media scan timer, such that when the media scan timer is satisfied, the memory system may be triggered to perform the media scan. In some examples, the block family scan timer may be associated with a relatively shorter duration (e.g., 1 hour) and the media scan timer may be associated with a relatively longer duration (e.g., 24 hours). For example, the block family scan timer may be associated with a duration that is shorter than an average duration (e.g., a power down duration) in which the memory system is powered down (e.g., before being powered up again at a subsequent time). Conversely, the media scan timer may be associated with a duration that is longer than an average duration in which the memory system is powered down.

In some cases, the block family timer and the media scan timer may not continue (e.g., to run, to count-down) while the memory system is powered down. For example, the block family timer and the media scan timer may pause at a value after the memory system is powered down, and continue from the value after the memory system is powered up again. In some cases, the memory system may be configured to automatically perform the block family scan based on powering up the memory system after the memory system was powered down. That is, the memory system may immediately perform the block family scan regardless of a value of the block family scan timer (e.g., regardless of whether the block family scan timer is satisfied or not). In some cases, the memory system may be configured to immediately perform the media scan based on powering up the memory system after the memory system was powered down. That is, the memory system may immediately perform the media scan regardless of a value of the media scan timer (e.g., regardless of whether the media scan timer is satisfied or not). However, in other cases, the memory system may be configured to refrain from performing the media scan based on powering up the memory system until the media scan timer is satisfied. That is, the memory system may continue the media scan timer from the value at which the media scan timer was paused after powering down the memory system, and the memory system may perform the media scan when the timer is satisfied.

The memory system may determine whether to immediately perform the media scan or refrain from performing the media scan after powering up the memory system based on results of the block family scan. That is, the process flow 200 illustrates operations performed by the memory system to determine whether to immediately perform the media scan or refrain from performing the media scan.

At 205, a power transition operation may be performed. The memory system may perform the power transition operation, which may be an example of a power up operation, by transitioning the memory system from the relatively low power mode to the relatively high power mode. In some cases, the power transition operation may be preceded by another power transition operation, which may be an example of a power down operation, in which the memory system transitioned from the relatively high power mode to the relatively low power mode. In some examples, the memory system may perform a media scan and a block family scan prior to performing the power transition operations, such that the media scan timer and the block family scan timer may have been continuing (e.g., running) prior to performing the power transition operations. In some such examples, the media scan timer and the block family scan timer may have been paused while performing the power down operation, such that after performing the power up operation, the media scan timer and the block family scan timer may continue from a value (e.g., a pre-power down value) saved prior to performing the power down operation.

At 210, a block family scan may be performed. The memory system may perform the block family scan based on performing the power transition operation. That is, the memory system may perform the block family scan immediately after the power transition operation, regardless of whether the block family scan timer is satisfied. The block family scan may be performed for one or more virtual blocks of the memory system (e.g., the virtual blocks of a memory device). After performing the block family scan, the memory system may restart the block family scan timer from an initial value associated with a start of the duration corresponding to the block family scan timer.

At 215, read voltages of the blocks may be identified. The memory system may identify the read voltages of the blocks based on performing the block family scan. For example, performing the block family scan may identify the read voltages for the blocks of the memory system. Likewise, performing the block family scan may identify the bins (e.g., Bin 0, Bin 1, Bin 2, . . . , etc.) for the blocks of the memory system. The memory system may identify a subset of the blocks (e.g., the blocks of a virtual block) with the lowest bin values (e.g., Bin 0) or the highest read voltages.

At 220, whether a change in the read voltages of the blocks satisfies a threshold may be determined. The memory system may determine whether a change in the read voltages of the subset of blocks satisfies a threshold based on identifying the subset of blocks with the lowest bin values or the highest read voltages. That is, for the blocks with the lowest bin values or the highest read voltages, the memory system may identify whether the bin values or the magnitudes of the read voltages have changed. For example, the memory system may determine whether the read voltages of the blocks with the highest read voltages have changed since performing a previous block family scan or since performing the power transition operation at step 205 of the process flow 200. Likewise, the memory system may determine whether the bin values of the blocks with the lowest bin values have changed.

In some cases, the memory system may determine whether a change in the read voltages of the blocks with the highest read voltages satisfies a threshold magnitude of change. In some such cases, determining whether the change in the read voltages satisfies the threshold magnitude of change may include determining whether a decrease in the read voltages satisfies a threshold. In some cases, the memory system may determine whether a change in the bin values of the blocks with the lowest bin values satisfies a threshold magnitude of change. In some such cases, determining whether the change in the bin value satisfies the threshold magnitude of change may include determining whether an increase in the bin values satisfies a threshold. In some examples, the memory system may determine that the change in the read voltages or the change in the bin values satisfies the threshold magnitude of change, and the process flow 200 may continue to step 235. In other examples, the memory system may determine that the change in the read voltages or the change in the bin values do not satisfy the threshold magnitude of change, and the process flow 200 may continue to step 225.

At 225, whether the magnitude of read voltages of the blocks satisfies a threshold may be determined. The memory system may determine whether the magnitude of the read voltages of the subset of blocks satisfies a threshold based on identifying the subset of blocks with the lowest bin values or the highest read voltages. That is, for the blocks with the lowest bin values or the highest read voltages, the memory system may identify whether the bin values or the magnitudes of the read voltages satisfy a threshold. For example, the memory system may determine whether the read voltages of the blocks with the highest read voltages satisfy a threshold voltage. In some such examples, determining whether the read voltages satisfy the threshold voltage may include determining whether the read voltages are less than a threshold voltage. In some examples, the memory system may determine whether the bin values of the blocks with the lowest bin values satisfy a threshold bin value. In some such examples, determining whether the bin values satisfy the threshold bin value may include determining whether the bin values are greater than the threshold bin value.

In some examples, the memory system may determine that the read voltages or the bin values satisfy the respective thresholds, and the process flow 200 may continue to step 235. In other examples, the memory system may determine that the read voltages or the bin values do not satisfy the respective thresholds, and the process flow 200 may continue to step 230. As shown, regarding step 220 and step 225 of the process flow 200, there are three scenarios in which the memory system may perform the operations of the process flow 200. In a first scenario, the memory system may determine that the change in the read voltages or the change in the bin values satisfy the respective thresholds, and the process flow 200 may continue to step 235. In a second scenario, the memory system may determine that the change in the read voltages or the change in the bin values do not satisfy the respective thresholds, and that the read voltages or the bin values satisfy the respective thresholds, then the process flow 200 may also continue to step 235. In a third scenario, the memory system may determine that the change in the read voltages or the change in the bin values do not satisfy the respective thresholds, and that the read voltages or the bin values do not satisfy the respective thresholds, then the process flow 200 may instead continue to step 230.

In some cases, the process flow 200 may be performed in an order such that step 225 occurs prior to step 220. For example, the memory system may determine whether the read voltages or the bin values satisfy the respective thresholds prior to determining whether the change in the read voltages or the change in the bin values satisfy the respective thresholds. That is, if step 220 and step 225 were reversed in order of the process flow 200, there are three scenarios in which the memory system may perform the operations of the process flow 200. In a first scenario, the memory system may determine that the read voltages or the bin values satisfy the respective thresholds, and the process flow 200 may continue to step 235. In a second scenario, the memory system may determine that the read voltages or the bin values do not satisfy the respective thresholds, and that the change in the read voltages or the change in the bin values satisfy the respective thresholds, then the process flow 200 may also continue to step 235. In a third scenario, the memory system may determine that the read voltages or the bin values do not satisfy the respective thresholds, and that the change in the read voltages or the change in the bin values do not satisfy the respective thresholds, then the process flow 200 may instead continue to step 230.

At 230, the media scan timer may be restarted. The memory system may restart the media scan timer, such that the media scan timer may continue from a value (e.g., a last saved value, a pre-power down value) saved prior to performing the power transition operation. That is, if the last saved value prior to performing the power transition operation indicated 23 hours remained from the 24 hour duration of the media scan timer, restarting the media scan timer at step 230 of the process flow 200 may set the media scan timer at 23 hours. Restarting the media scan timer may cause the memory system to refrain from immediately performing the media scan. That is, the memory system may wait to perform the media scan until the media scan timer is satisfied, beginning from the restarted value (e.g., 23 hours). In some cases, the process flow 200 may continue to step 245 after restarting the media scan timer to the last saved value, such that the memory system may perform the media scan after the media scan timer has elapsed.

At 235, the media scan timer may be reset. The memory system may reset the media scan timer, such that the media scan timer may be immediately satisfied. Resetting the media scan timer may trigger the memory system to immediately perform the media scan. In some cases, resetting the media scan timer to trigger immediately perform the media scan may restart the media scan timer from an initial value associated with a start of the duration corresponding to the media scan timer. In some cases, the process flow 200 may immediately continue to step 240 after resetting the media scan timer, such that the memory system may perform the media scan immediately after resetting the media scan timer.

At 240, the media scan may be performed. The memory system may perform the media scan based on the media scan timer being reset. For example, the memory system may perform the media scan based on the media scan timer being reset, such that the media scan timer may trigger the memory system to immediately perform the media scan. After performing the media scan, the memory system may restart the media scan timer from an initial value associated with a start of the duration corresponding to the media scan timer.

Performing the media scan may include identifying a level of degradation or a retention capability of the blocks. After identifying a level of degradation, the memory system may determine whether the level of degradation satisfies a threshold level of degradation. If the memory system determines that the level of degradation satisfies a threshold level of degradation, the memory system may perform a refresh operation on the blocks. If the memory system determines that the level of degradation does not satisfy a threshold level of degradation, the memory system may refrain from performing a refresh operation on the blocks.

At 245, the media scan may be performed based on the media scan timer elapsing. The memory system may perform the media scan based on the media scan timer being restarted at step 240 after performing the media scan and the media scan timer being later satisfied, or based on the media scan timer being restarted at step 230 and the media scan timer being later satisfied. For example, the memory system may immediately perform the media scan at step 240 after resetting the media scan timer, and may restart the media scan timer from an initial value (e.g., associated with a start of the duration corresponding to the media scan timer). Based on the media scan timer eventually elapsing again, the media scan timer may trigger the memory system to perform another media scan. Conversely, the memory system may perform the media scan based on the media scan timer being restarted at step 230, such that the media scan timer may continue from a last saved value until being satisfied, at which time the media scan timer may trigger the memory system to perform the media scan. After performing the media scan at 245, the memory system may restart the media scan timer from the initial value.

At 250, the block family scan may be performed. The memory system may perform the block family scan based on the block family scan timer being satisfied (e.g., having elapsed). That is, after restarting the block family scan timer to the initial value at step 210 of the process flow 200, the block family scan timer may eventually be satisfied, and the memory system may reperform the block family scan.

Dynamically adjusting the timing for performing the media scan may prevent retention and/or degradation of the memory system otherwise associated with not performing the media scan after the memory system is powered down (e.g., and powered on again). Likewise, dynamically adjusting the timing for performing the media scan may prevent latency and bandwidth consumption otherwise associated with performing an unnecessary media scan after the memory system is powered down (e.g., and powered on again).

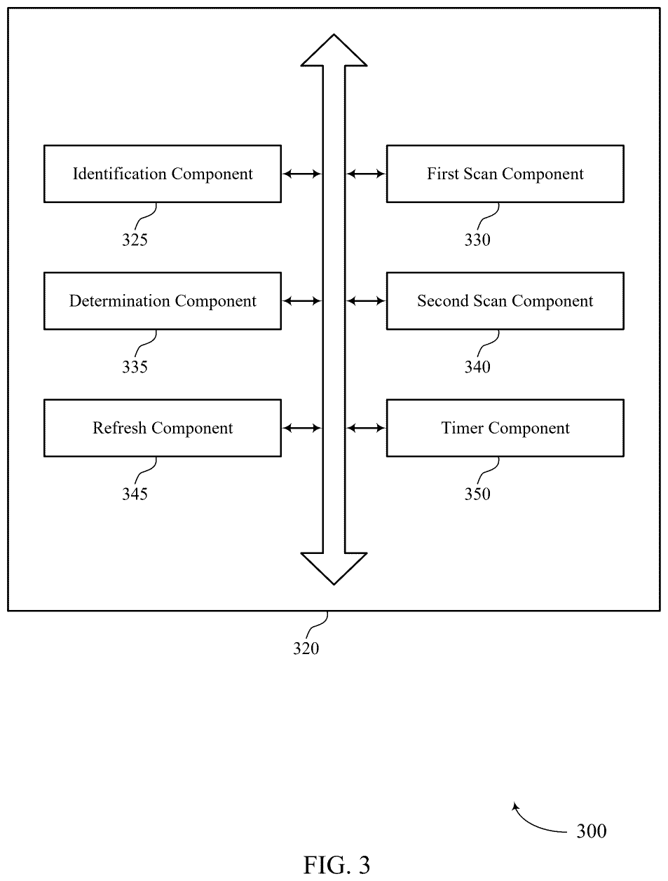

FIG. 3 shows a block diagram 300 of a memory system 320 that supports scan timing management for a memory system in accordance with examples as disclosed herein. The memory system 320 may be an example of aspects of a memory system as described with reference to FIGS. 1 through 2. The memory system 320, or various components thereof, may be an example of means for performing various aspects of scan timing management for a memory system as described herein. For example, the memory system 320 may include an identification component 325, a first scan component 330, a determination component 335, a second scan component 340, a refresh component 345, a timer component 350, or any combination thereof. Each of these components, or components of subcomponents thereof (e.g., one or more processors, one or more memories), may communicate, directly or indirectly, with one another (e.g., via one or more buses).

The identification component 325 may be configured as or otherwise support a means for identifying a change in power level of the memory system from a first power level to a second power level. The first scan component 330 may be configured as or otherwise support a means for performing, after the change in power level, a first scan operation on a plurality of blocks of the memory system to identify one or more read voltages associated with the plurality of blocks. The determination component 335 may be configured as or otherwise support a means for determining, in accordance with the one or more read voltages identified via the first scan operation, whether to perform a second scan operation on the plurality of blocks, the second scan operation to identify one or more levels of degradation for the plurality of blocks.

In some examples, to support determining whether to perform the second scan operation on the plurality of blocks, the determination component 335 may be configured as or otherwise support a means for determining, for at least a subset of blocks included in the plurality of blocks, whether a change in read voltage satisfies a change threshold, the change in read voltage including a difference between a prior read voltage associated with at least the subset of blocks before the change in power level and a new read voltage identified for at least the subset of blocks via the first scan operation.

In some examples, the second scan component 340 may be configured as or otherwise support a means for performing the second scan operation in response to determining that the change in read voltage satisfies the change threshold.

In some examples, the timer component 350 may be configured as or otherwise support a means for resetting a timer associated with the second scan operation in response to determining that the change in read voltage satisfies the change threshold, where performing the second scan operation is in response to the timer associated with the second scan operation being reset.

In some examples, to support determining whether to perform the second scan operation on the plurality of blocks, the determination component 335 may be configured as or otherwise support a means for determining whether the new read voltage identified for at least the subset of blocks via the first scan operation satisfies a threshold.

In some examples, determining whether the new read voltage satisfies a threshold occurs in response to determining that the change in read voltage does not satisfy the change threshold.

In some examples, the second scan component 340 may be configured as or otherwise support a means for refraining from performing the second scan operation in response to determining that the change in read voltage does not satisfy the change threshold and that the new read voltage does not satisfy the threshold.

In some examples, the timer component 350 may be configured as or otherwise support a means for restarting, in response to determining that the new read voltage does not satisfy the threshold, a timer associated with the second scan operation from a saved value of the timer, the saved value of the timer from before the change in power level.

In some examples, the one or more read voltages include a plurality of read voltages identified via the first scan operation. In some examples, the subset of blocks is associated with a lowest read voltage or a highest read voltage from among the plurality of read voltages.

In some examples, to support determining whether to perform the second scan operation on the plurality of blocks, the determination component 335 may be configured as or otherwise support a means for determining, for at least a subset of blocks included in the plurality of blocks, whether a read voltage identified for at least the subset of blocks via the first scan operation satisfies a threshold.

In some examples, the second scan component 340 may be configured as or otherwise support a means for performing the second scan operation in response to determining that the read voltage satisfies the threshold.

In some examples, the timer component 350 may be configured as or otherwise support a means for resetting a timer associated with the second scan operation in response to determining that the read voltage satisfies the threshold, where performing the second scan operation is in response to the timer associated with the second scan operation being reset.

In some examples, to support determining whether to perform the second scan operation on the plurality of blocks, the determination component 335 may be configured as or otherwise support a means for determining, in response to determining that the read voltage does not satisfy the threshold, whether a change in read voltage for at least the subset of blocks satisfies a change threshold, the change in read voltage including a difference between a prior read voltage associated with at least the subset of blocks before the change in power level and the read voltage identified for at least the subset of blocks via the first scan operation. In some examples, the second scan component 340 may be configured as or otherwise support a means for refraining from performing the second scan operation in response to determining that the change in read voltage does not satisfy the change threshold and that the read voltage does not satisfy the threshold.

In some examples, to support determining whether to perform the second scan operation on the plurality of blocks, the determination component 335 may be configured as or otherwise support a means for determining, for at least a subset of blocks included in the plurality of blocks, at least one of: whether a change in read voltage satisfies a change threshold, the change in read voltage including a difference between a prior read voltage associated with at least the subset of blocks before the change in power level and a new read voltage identified for at least the subset of blocks via the first scan operation; or whether the new read voltage identified for at least the subset of blocks via the first scan operation satisfies a threshold. In some examples, the second scan component 340 may be configured as or otherwise support a means for performing the second scan operation in response to determining that the change in read voltage satisfies the change threshold, that the new read voltage satisfies the threshold, or both. In some examples, the second scan component 340 may be configured as or otherwise support a means for refraining from performing the second scan operation in response to determining that the change in read voltage does not satisfy the change threshold and that the new read voltage does not satisfy the threshold.

In some examples, the second scan component 340 may be configured as or otherwise support a means for performing the second scan operation in response to determining, in accordance with the one or more read voltages identified via the first scan operation, to perform the second scan operation. In some examples, the determination component 335 may be configured as or otherwise support a means for determining, via the second scan operation, whether a level of degradation for one or more blocks from among the plurality of blocks satisfies a threshold level of degradation. In some examples, the refresh component 345 may be configured as or otherwise support a means for performing one or more refresh operations on the one or more blocks in response to determining that the level of degradation for the one or more blocks satisfies the threshold level of degradation.

In some examples, to support identifying the one or more read voltages associated with the plurality of blocks, the first scan component 330 may be configured as or otherwise support a means for identifying a respective bin value for each block of the plurality of blocks, where the respective bin value for a block corresponds to respective range of voltages that includes a voltage associated with reading memory cells within the block, and where the one or more read voltages include one or more bin values associated with the plurality of blocks.

In some examples, the described functionality of the memory system 320, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 320, or various components thereof, may be implemented at least in part by instructions (e.g., stored in memory, non-transitory computer-readable medium) executable by such at least one processor.

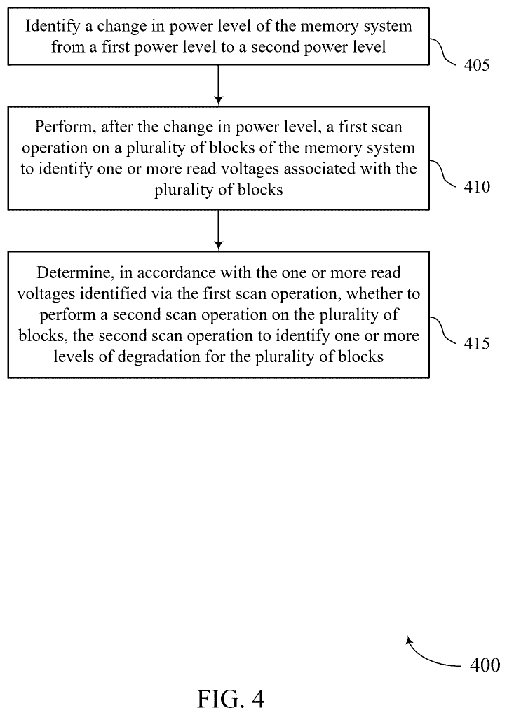

FIG. 4 shows a flowchart illustrating a method 400 that supports scan timing management for a memory system in accordance with examples as disclosed herein. The operations of method 400 may be implemented by a memory system or its components as described herein. For example, the operations of method 400 may be performed by a memory system as described with reference to FIGS. 1 through 3. In some examples, a memory system may execute a set of instructions to control the functional elements of the device to perform the described functions. Additionally, or alternatively, the memory system may perform aspects of the described functions using special-purpose hardware.

At 405, the method may include identifying a change in power level of the memory system from a first power level to a second power level. In some examples, aspects of the operations of 405 may be performed by an identification component 325 as described with reference to FIG. 3.

At 410, the method may include performing, after the change in power level, a first scan operation on a plurality of blocks of the memory system to identify one or more read voltages associated with the plurality of blocks. In some examples, aspects of the operations of 410 may be performed by a first scan component 330 as described with reference to FIG. 3.

At 415, the method may include determining, in accordance with the one or more read voltages identified via the first scan operation, whether to perform a second scan operation on the plurality of blocks, the second scan operation to identify one or more levels of degradation for the plurality of blocks. In some examples, aspects of the operations of 415 may be performed by a determination component 335 as described with reference to FIG. 3.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for identifying a change in power level of the memory system from a first power level to a second power level; performing, after the change in power level, a first scan operation on a plurality of blocks of the memory system to identify one or more read voltages associated with the plurality of blocks; and determining, in accordance with the one or more read voltages identified via the first scan operation, whether to perform a second scan operation on the plurality of blocks, the second scan operation to identify one or more levels of degradation for the plurality of blocks.
Aspect 2: The method, apparatus, or non-transitory computer-readable medium of aspect 1, where operations, features, circuitry, logic, means, or instructions, or any combination thereof for determining whether to perform the second scan operation on the plurality of blocks includes operations, features, circuitry, logic, means, or instructions, or any combination thereof for determining, for at least a subset of blocks included in the plurality of blocks, whether a change in read voltage satisfies a change threshold, the change in read voltage including a difference between a prior read voltage associated with at least the subset of blocks before the change in power level and a new read voltage identified for at least the subset of blocks via the first scan operation.
Aspect 3: The method, apparatus, or non-transitory computer-readable medium of aspect 2, further including operations, features, circuitry, logic, means, or instructions, or any combination thereof for performing the second scan operation in response to determining that the change in read voltage satisfies the change threshold.
Aspect 4: The method, apparatus, or non-transitory computer-readable medium of aspect 3, further including operations, features, circuitry, logic, means, or instructions, or any combination thereof for resetting a timer associated with the second scan operation in response to determining that the change in read voltage satisfies the change threshold, where performing the second scan operation is in response to the timer associated with the second scan operation being reset.
Aspect 5: The method, apparatus, or non-transitory computer-readable medium of any of aspects 2 through 4, where operations, features, circuitry, logic, means, or instructions, or any combination thereof for determining whether to perform the second scan operation on the plurality of blocks further includes operations, features, circuitry, logic, means, or instructions, or any combination thereof for determining whether the new read voltage identified for at least the subset of blocks via the first scan operation satisfies a threshold.
Aspect 6: The method, apparatus, or non-transitory computer-readable medium of aspect 5, where determining whether the new read voltage satisfies a threshold occurs in response to determining that the change in read voltage does not satisfy the change threshold.
Aspect 7: The method, apparatus, or non-transitory computer-readable medium of any of aspects 5 through 6, further including operations, features, circuitry, logic, means, or instructions, or any combination thereof for refraining from performing the second scan operation in response to determining that the change in read voltage does not satisfy the change threshold and that the new read voltage does not satisfy the threshold.
Aspect 8: The method, apparatus, or non-transitory computer-readable medium of aspect 7, further including operations, features, circuitry, logic, means, or instructions, or any combination thereof for restarting, in response to determining that the new read voltage does not satisfy the threshold, a timer associated with the second scan operation from a saved value of the timer, the saved value of the timer from before the change in power level.
Aspect 9: The method, apparatus, or non-transitory computer-readable medium of any of aspects 2 through 8, where the one or more read voltages include a plurality of read voltages identified via the first scan operation and the subset of blocks is associated with a lowest read voltage or a highest read voltage from among the plurality of read voltages.
Aspect 10: The method, apparatus, or non-transitory computer-readable medium of any of aspects 1 through 9, where operations, features, circuitry, logic, means, or instructions, or any combination thereof for determining whether to perform the second scan operation on the plurality of blocks includes operations, features, circuitry, logic, means, or instructions, or any combination thereof for determining, for at least a subset of blocks included in the plurality of blocks, whether a read voltage identified for at least the subset of blocks via the first scan operation satisfies a threshold.
Aspect 11: The method, apparatus, or non-transitory computer-readable medium of aspect 10, further including operations, features, circuitry, logic, means, or instructions, or any combination thereof for performing the second scan operation in response to determining that the read voltage satisfies the threshold.
Aspect 12: The method, apparatus, or non-transitory computer-readable medium of any of aspects 10 through 11, further including operations, features, circuitry, logic, means, or instructions, or any combination thereof for resetting a timer associated with the second scan operation in response to determining that the read voltage satisfies the threshold, where performing the second scan operation is in response to the timer associated with the second scan operation being reset.
Aspect 13: The method, apparatus, or non-transitory computer-readable medium of any of aspects 10 through 12, where operations, features, circuitry, logic, means, or instructions, or any combination thereof for determining whether to perform the second scan operation on the plurality of blocks further includes operations, features, circuitry, logic, means, or instructions, or any combination thereof for determining, in response to determining that the read voltage does not satisfy the threshold, whether a change in read voltage for at least the subset of blocks satisfies a change threshold, the change in read voltage including a difference between a prior read voltage associated with at least the subset of blocks before the change in power level and the read voltage identified for at least the subset of blocks via the first scan operation, and where the method, apparatus, or non-transitory computer-readable medium further include operations, features, circuitry, logic, means, or instructions, or any combination thereof for refraining from performing the second scan operation in response to determining that the change in read voltage does not satisfy the change threshold and that the read voltage does not satisfy the threshold.
Aspect 14: The method, apparatus, or non-transitory computer-readable medium of any of aspects 1 through 13, where operations, features, circuitry, logic, means, or instructions, or any combination thereof for determining whether to perform the second scan operation on the plurality of blocks includes operations, features, circuitry, logic, means, or instructions, or any combination thereof for determining, for at least a subset of blocks included in the plurality of blocks, at least one of: whether a change in read voltage satisfies a change threshold, the change in read voltage including a difference between a prior read voltage associated with at least the subset of blocks before the change in power level and a new read voltage identified for at least the subset of blocks via the first scan operation; or whether the new read voltage identified for at least the subset of blocks via the first scan operation satisfies a threshold; the method, apparatus, or non-transitory computer-readable medium further including operations, features, circuitry, logic, means, or instructions, or any combination thereof for: performing the second scan operation in response to determining that the change in read voltage satisfies the change threshold, that the new read voltage satisfies the threshold, or both; and refraining from performing the second scan operation in response to determining that the change in read voltage does not satisfy the change threshold and that the new read voltage does not satisfy the threshold.
Aspect 15: The method, apparatus, or non-transitory computer-readable medium of any of aspects 1 through 14, further including operations, features, circuitry, logic, means, or instructions, or any combination thereof for performing the second scan operation in response to determining, in accordance with the one or more read voltages identified via the first scan operation, to perform the second scan operation; determining, via the second scan operation, whether a level of degradation for one or more blocks from among the plurality of blocks satisfies a threshold level of degradation; and performing one or more refresh operations on the one or more blocks in response to determining that the level of degradation for the one or more blocks satisfies the threshold level of degradation.
Aspect 16: The method, apparatus, or non-transitory computer-readable medium of any of aspects 1 through 15, where operations, features, circuitry, logic, means, or instructions, or any combination thereof for identifying the one or more read voltages associated with the plurality of blocks includes operations, features, circuitry, logic, means, or instructions, or any combination thereof for identifying a respective bin value for each block of the plurality of blocks, where the respective bin value for a block corresponds to respective range of voltages that includes a voltage associated reading memory cells within the block, and where the one or more read voltages include one or more bin values associated with the plurality of blocks.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
identify a change in power level of the memory system from a first power level to a second power level;
perform, after the change in power level, a first scan operation on a plurality of blocks of the memory system to identify one or more read voltages associated with the plurality of blocks; and
determine, in accordance with the one or more read voltages identified via the first scan operation, whether to perform a second scan operation on the plurality of blocks, the second scan operation to identify one or more levels of degradation for the plurality of blocks.

2. The memory system of claim 1, wherein, to determine whether to perform the second scan operation on the plurality of blocks, the processing circuitry is configured to cause the memory system to:
determine, for at least a subset of blocks included in the plurality of blocks, whether a change in read voltage satisfies a change threshold, the change in read voltage comprising a difference between a prior read voltage associated with at least the subset of blocks before the change in power level and a new read voltage identified for at least the subset of blocks via the first scan operation.

3. The memory system of claim 2, wherein the processing circuitry is further configured to cause the memory system to:
perform the second scan operation in response to determining that the change in read voltage satisfies the change threshold.

4. The memory system of claim 3, wherein the processing circuitry is further configured to cause the memory system to:
reset a timer associated with the second scan operation in response to determining that the change in read voltage satisfies the change threshold, wherein the processing circuitry is configured to cause the memory system to perform the second scan operation in response to the timer associated with the second scan operation being reset.

5. The memory system of claim 2, wherein, to determine whether to perform the second scan operation on the plurality of blocks, the processing circuitry is configured to cause the memory system to:
determine whether the new read voltage identified for at least the subset of blocks via the first scan operation satisfies a threshold.

6. The memory system of claim 5, wherein the processing circuitry is configured to cause the memory system to determine whether the new read voltage satisfies a threshold in response to determining that the change in read voltage does not satisfy the change threshold.

7. The memory system of claim 5, wherein the processing circuitry is further configured to cause the memory system to:
refrain from performing the second scan operation in response to determining that the change in read voltage does not satisfy the change threshold and that the new read voltage does not satisfy the threshold.

8. The memory system of claim 7, wherein the processing circuitry is further configured to cause the memory system to:
restart, in response to determine that the new read voltage does not satisfy the threshold, a timer associated with the second scan operation from a saved value of the timer, the saved value of the timer from before the change in power level.

9. The memory system of claim 2, wherein:
the one or more read voltages comprise a plurality of read voltages identified via the first scan operation, and
the subset of blocks is associated with a lowest read voltage or a highest read voltage from among the plurality of read voltages.

10. The memory system of claim 1, wherein, to determine whether to perform the second scan operation on the plurality of blocks, the processing circuitry is configured to cause the memory system to:
determine, for at least a subset of blocks included in the plurality of blocks, whether a read voltage identified for at least the subset of blocks via the first scan operation satisfies a threshold.

11. The memory system of claim 10, wherein the processing circuitry is further configured to cause the memory system to:
perform the second scan operation in response to determining that the read voltage satisfies the threshold.

12. The memory system of claim 10, wherein the processing circuitry is further configured to cause the memory system to:
reset a timer associated with the second scan operation in response to determining that the read voltage satisfies the threshold, wherein the processing circuitry is configured to cause the memory system to perform the second scan operation in response to the timer associated with the second scan operation being reset.

13. The memory system of claim 10, wherein:
to determining whether to perform the second scan operation on the plurality of blocks, the processing circuitry is further configured to cause the memory system to determine, in response to determining that the read voltage does not satisfy the threshold, whether a change in read voltage for at least the subset of blocks satisfies a change threshold, the change in read voltage comprising a difference between a prior read voltage associated with at least the subset of blocks before the change in power level and the read voltage identified for at least the subset of blocks via the first scan operation; and
the processing circuitry is further configured to cause the memory system to refrain from performing the second scan operation in response to determining that the change in read voltage does not satisfy the change threshold and that the read voltage does not satisfy the threshold.

14. The memory system of claim 1, wherein:
to determine whether to perform the second scan operation on the plurality of blocks, the processing circuitry is configured to cause the memory system to determine, for at least a subset of blocks included in the plurality of blocks, at least one of:
whether a change in read voltage satisfies a change threshold, the change in read voltage comprising a difference between a prior read voltage associated with at least the subset of blocks before the change in power level and a new read voltage identified for at least the subset of blocks via the first scan operation; or
whether the new read voltage identified for at least the subset of blocks via the first scan operation satisfies a threshold; and
the processing circuitry further is configured to cause the memory system to:
perform the second scan operation in response to determining that the change in read voltage satisfies the change threshold, that the new read voltage satisfies the threshold, or both; and
refrain from performing the second scan operation in response to determining that the change in read voltage does not satisfy the change threshold and that the new read voltage does not satisfy the threshold.

15. The memory system of claim 1, wherein the processing circuitry is further configured to cause the memory system to:
perform the second scan operation in response to determining, in accordance with the one or more read voltages identified via the first scan operation, to perform the second scan operation;
determine, via the second scan operation, whether a level of degradation for one or more blocks from among the plurality of blocks satisfies a threshold level of degradation; and
perform one or more refresh operations on the one or more blocks in response to determining that the level of degradation for the one or more blocks satisfies the threshold level of degradation.

16. The memory system of claim 1, wherein, to identify the one or more read voltages associated with the plurality of blocks, the processing circuitry is configured to cause the memory system to:
identify a respective bin value for each block of the plurality of blocks, wherein the respective bin value for a block corresponds to respective range of voltages that includes a voltage associated with reading memory cells within the block, and wherein the one or more read voltages comprise one or more bin values associated with the plurality of blocks.

17. A non-transitory computer-readable medium storing code, the code comprising instructions executable by one or more processors to:
identify a change in power level of a memory system from a first power level to a second power level;
perform, after the change in power level, a first scan operation on a plurality of blocks of the memory system to identify one or more read voltages associated with the plurality of blocks; and
determine, in accordance with the one or more read voltages identified via the first scan operation, whether to perform a second scan operation on the plurality of blocks, the second scan operation to identify one or more levels of degradation for the plurality of blocks.

18. The non-transitory computer-readable medium of claim 17, wherein, to determine whether to perform the second scan operation on the plurality of blocks, the instructions are executable by the one or more processors to:
determine, for at least a subset of blocks included in the plurality of blocks, whether a change in read voltage satisfies a change threshold, the change in read voltage comprising a difference between a prior read voltage associated with at least the subset of blocks before the change in power level and a new read voltage identified for at least the subset of blocks via the first scan operation.

19. The non-transitory computer-readable medium of claim 18, wherein the instructions are further executable by the one or more processors to:
perform the second scan operation in response to determining that the change in read voltage satisfies the change threshold.

20. The non-transitory computer-readable medium of claim 19, wherein the instructions are further executable by the one or more processors to:
reset a timer associated with the second scan operation in response to determining that the change in read voltage satisfies the change threshold, wherein the instructions are executable by the one or more processors to perform the second scan operation in response to the timer associated with the second scan operation being reset.

21. The non-transitory computer-readable medium of claim 18, wherein, to determine whether to perform the second scan operation on the plurality of blocks, the instructions are executable by the one or more processors to:
determine whether the new read voltage identified for at least the subset of blocks via the first scan operation satisfies a threshold.

22. The non-transitory computer-readable medium of claim 21, wherein the instructions are further executable by the one or more processors to:
refrain from performing the second scan operation in response to determining that the change in read voltage does not satisfy the change threshold and that the new read voltage does not satisfy the threshold.

23. The non-transitory computer-readable medium of claim 17, wherein, to determine whether to perform the second scan operation on the plurality of blocks, the instructions are executable by the one or more processors to:
determine, for at least a subset of blocks included in the plurality of blocks, whether a read voltage identified for at least the subset of blocks via the first scan operation satisfies a threshold.

24. The non-transitory computer-readable medium of claim 23, wherein the instructions are further executable by the one or more processors to:
perform the second scan operation in response to determining that the read voltage satisfies the threshold.

25. A method by a memory system, comprising:
identifying a change in power level of the memory system from a first power level to a second power level;
performing, after the change in power level, a first scan operation on a plurality of blocks of the memory system to identify one or more read voltages associated with the plurality of blocks; and
determining, in accordance with the one or more read voltages identified via the first scan operation, whether to perform a second scan operation on the plurality of blocks, the second scan operation to identify one or more levels of degradation for the plurality of blocks.
